(19) United States
(12) Patent Application Publication
(10) Pub. No.: US 2026/0123356 A1
(43) Pub. Date: Apr. 30, 2026

(54) METHOD FOR DETERMINING DEBONDING PARAMETER VALUE AND DEBONDING METHOD USING DEBONDING PARAMETER VALUE

(71) Applicant: TAIWAN SEMICONDUCTOR MANUFACTURING COMPANY, LTD., Hsinchu (TW)

(72) Inventors: Zheng-Yong LIANG, Hsinchu (TW); Yu-Yun PENG, Hsinchu (TW); Keng-Chu LIN, Hsinchu (TW); Wei-Ting YEH, Hsinchu (TW); I-Han HUANG, Hsinchu (TW); Yi-Chien WANG, Hsinchu (TW)

(73) Assignee: TAIWAN SEMICONDUCTOR MANUFACTURING COMPANY, LTD., Hsinchu (TW)

(21) Appl. No.: 18/930,712

(22) Filed: Oct. 29, 2024

(51) Int. Cl. H01L 21/66; B32B 41/00; B32B 43/00; H01L 21/78

(52) U.S. Cl. CPC H10P 74/203; B32B 41/00; B32B 43/006; H10P 95/112; B32B 2457/14

(57) ABSTRACT

A method for determining a parameter value to be used in a debonding tool includes: performing a debonding process to debond a carrier wafer from a control wafer using a debonding parameter with an initial test value that is in a range between a first end value and a second end value; determining whether the debonding process meets a criterion; determining, when it is determined that the debonding process meets the criterion, whether a crystal phase of a temperature sensitive layer located between the carrier wafer and the control wafer is changed; and determining, when it is determined that the crystal phase of the temperature sensitive layer is not changed, a current value of the debonding parameter as a value of another debonding parameter for another debonding process.

### BACKGROUND

With dramatic advances in semiconductor technology, the dimension of semiconductor devices, such as metal oxide semiconductor field effect transistors (MOSFETs) is continuously scaled down, and the MOSFETs may be stacked vertically to form a three-dimensional integrated circuit (3DIC) with reduced power consumption and smaller footprint compared to conventional two-dimensional processes, so as to achieve improvement in performance. The concept of 3DIC applies not only to the local (transistor) level, but also to the intermediate (bond pad) level and the global (package) level. Wafer bonding or wafer stacking is a 3D packaging technology for stacking multiple wafers together, and is still undergoing vigorous development.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram illustrating a system in accordance with some embodiments.

FIG. 2A is a flow diagram illustrating a method for determining a parameter value to be used in a debonding tool using the system shown in FIG. 1 in accordance with some embodiments.

FIG. 2B is a flow diagram illustrating a method for manufacturing a first bonded structure in accordance with some embodiments.

FIG. 2C is a flow diagram illustrating a method for manufacturing a second bonded structure in accordance with some embodiments.

FIGS. 3 to 12 illustrate schematic views of intermediate stages of the method depicted in FIG. 1 in accordance with some embodiments.

FIG. 13 is a flow diagram illustrating a method for manufacturing a semiconductor structure in accordance with some embodiments.

FIGS. 14 to 21 illustrate schematic views of intermediate stages of the method depicted in FIG. 13 in accordance with some embodiments.

FIGS. 22 to 26 are schematic views respectively similar to those of FIGS. 3 to 7, but illustrating the intermediate stages of the method depicted in FIG. 1 in accordance with some other embodiments.

FIG. 27 is a flow diagram similar to that of FIG. 2A, but illustrating the method in accordance with some other embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the terms “about” and “substantially” even if the terms “about” and “substantially” are not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the terms “about” and “substantially,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

In 3DIC (three-dimensional integrated circuit) semiconductor packaging technology, a bonding process and a debonding process may be performed. In the bonding process, a first carrier wafer is bonded to a front surface of a semiconductor structure so that the semiconductor structure can be supported by the first carrier wafer when the semiconductor structure is flipped to place a back surface thereof facing upward. The front surface and the back surface are opposite to each other. After processing the semiconductor structure from the back surface thereof, a second carrier wafer is bonded to the back surface of the semiconductor structure, and then the semiconductor structure is flipped again to place the front surface thereof facing upward. Next, in the debonding process, the first carrier wafer is separated from the front surface of the semiconductor structure so as to permit the semiconductor structure to be further processed from the front surface thereof. After the debonding process, the first carrier wafer can be reused again. In certain cases, a laser is used in the debonding process to selectively heat a debonding structure which is located between the first carrier wafer and the semiconductor structure. During the debonding process, the semiconductor structure is inevitably heated to a certain temperature due to thermal conduction, and the semiconductor structure may be damaged when the temperature of the semiconductor structure is higher than a certain temperature. Since the temperature of the semiconductor structure during the debonding process is difficult be in-situ measured, therefore, the present disclosure is directed to a method for determining a parameter value to be used in a debonding tool. When the parameter value is used in a debonding process for separating the first carrier wafer from the semiconductor structure, the damage to the semiconductor structure caused by overheating of the semiconductor structure may be prevented.

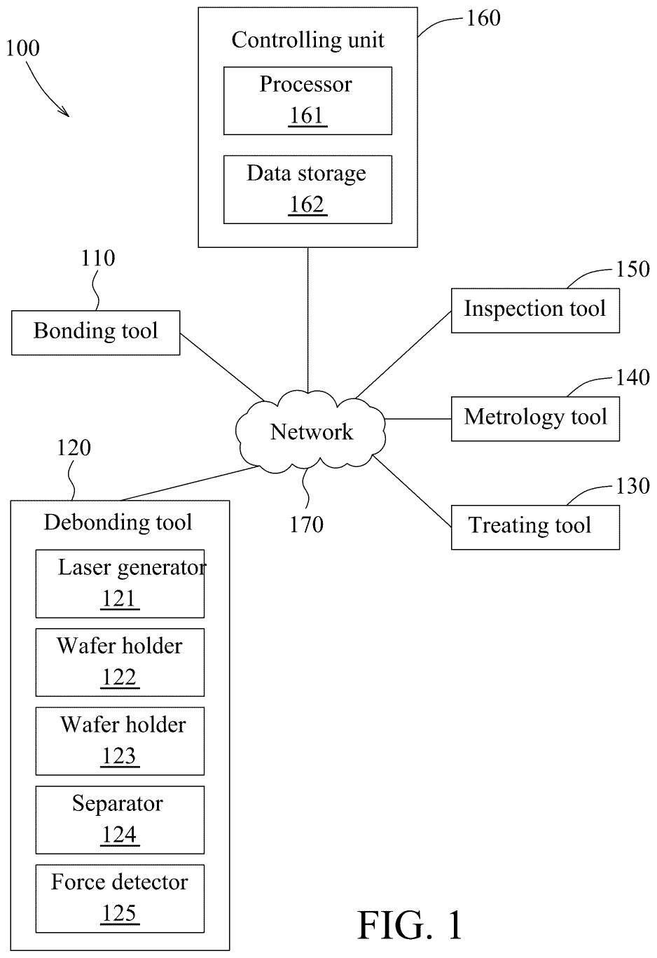

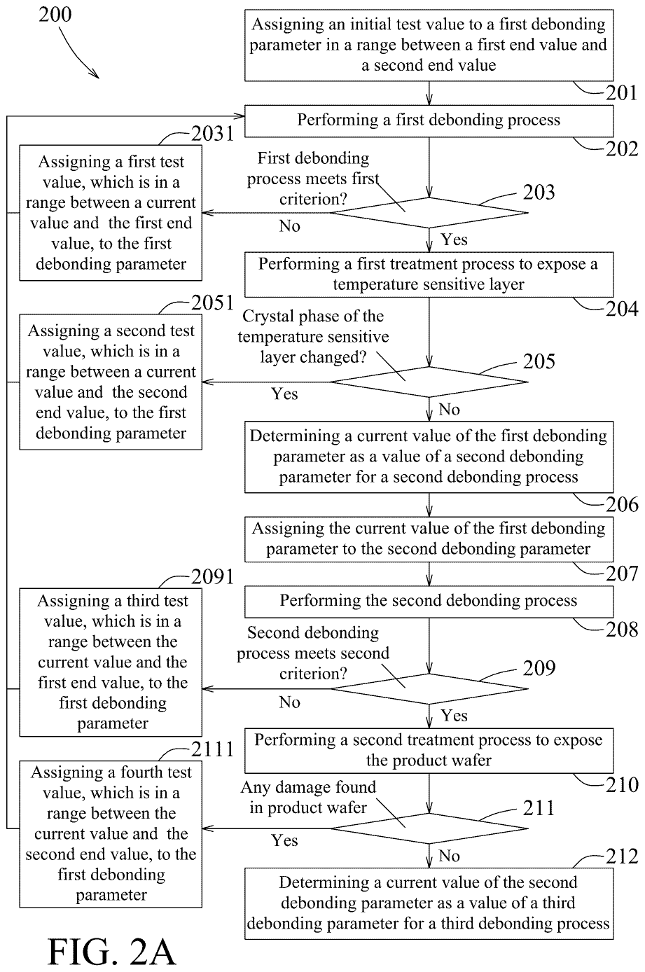

FIG. 1 is a block diagram illustrating a system 100 in which a method (for example, but not limited to, a method 200 shown in FIG. 2A) can be implemented in accordance with some embodiments.

The system 100 includes a bonding tool 110, a debonding tool 120, a treating tool 130, a metrology tool 140, a defect inspection tool 150, and a controlling unit 160 each of which is connected to a communication network 170. In some embodiments, the communication network 170 may be a single network or may be a variety of different networks, such as an intranet and the Internet, and may include both wired and wireless communication channels. Each of the components 110, 120, 130, 140, 150, 160, 170 is equipped with a communication unit so that each component may interact with other components and may provide services to and/or receive services from the other components through the communication network 170.

In some embodiments, the bonding tool 110 is used to bond two semiconductor wafers together to form a wafer stack or a bonded structure. In some embodiments, the two semiconductor wafers may include a carrier wafer and a product wafer that is formed with electronic devices (such as active devices, passive devices, memory devices, etc.) and/or an interconnect structure (such as super power rail, power delivery network, etc.). Other wafers suitable to be bonded together are also within the contemplated scope of the present disclosure. The debonding tool 120 is used to separate the two semiconductor wafers from each other in a debonding process. In some embodiments, the debonding tool 120 includes a laser generator 121 for generating a laser, a wafer holder 122 for retaining a first semiconductor wafer thereon, a wafer holder 123 for retaining a second semiconductor wafer, a separator 124 for applying a force to move the second semiconductor wafer away from the first semiconductor wafer, and a force detector 125 for detecting the force applied by the separator 124 during a debonding process for separating the first and second semiconductor wafers. In some embodiments, the force detector 125 includes a force sensor, a force gauge, a force meter or other suitable devices for force sensing. The treating tool 130 is used to prepare a post-debonded structure into a sample suitable for measurement by the metrology tool 140 or inspection by the inspection tool 150. In some embodiments, the treating tool 130 includes a grinding tool, a polishing tool, a chemical mechanical polishing tool, or other tools suitable for sample preparation. The metrology tool 140 is used to analyze the crystal phase of a sample or analyze the post-debonded structure. In some embodiments, the metrology tool 140 includes transmission electron microscope (TEM), grazing incidence X-ray diffractometer (GIXRD), or other tools suitable for crystal phase analysis. The defect inspection tool 150 is used to perform pattern inspection for detecting defective states (such as short-circuiting, wire disconnections, pad damage, etc.) of the pattern to be inspected and perform particle inspection for detecting foreign particles on the pattern. In some embodiments, the inspection tool 150 includes a KLA-Tencor equipment. The controlling unit 160 may be embodied using a server, an industrial computer, a personal computer, a laptop or other suitable devices. In some embodiments, the controlling unit 160 includes a processor 161 and a data storage 162. The processor 161 may be embodied using a central processing unit (CPU), a microprocessor, a microcontroller, a single core processor, a multi-core processor, a dual-core mobile processor, a microprocessor, a microcontroller, a digital signal processor (DSP), a field-programmable gate array (FPGA), an application specific integrated circuit (ASIC), a radio-frequency integrated circuit (RFIC), and/or other suitable processors. The data storage 162 is connected to the processor 161, and is configured to store data received from the other components 110, 120, 130, 140, 150 and to store applicable data for the other components 110, 120, 130, 140, 150 (such as applicable debonding data for the debonding tool 120). The data storage 162 may be embodied using, for example, random access memory (RAM), read only memory (ROM), programmable ROM (PROM), firmware, flash memory, etc. In some embodiments, the data storage 162 stores a software application therein. The software application includes instructions that, when executed by the processor 161, cause the processor 161 to implement the operations as described below.

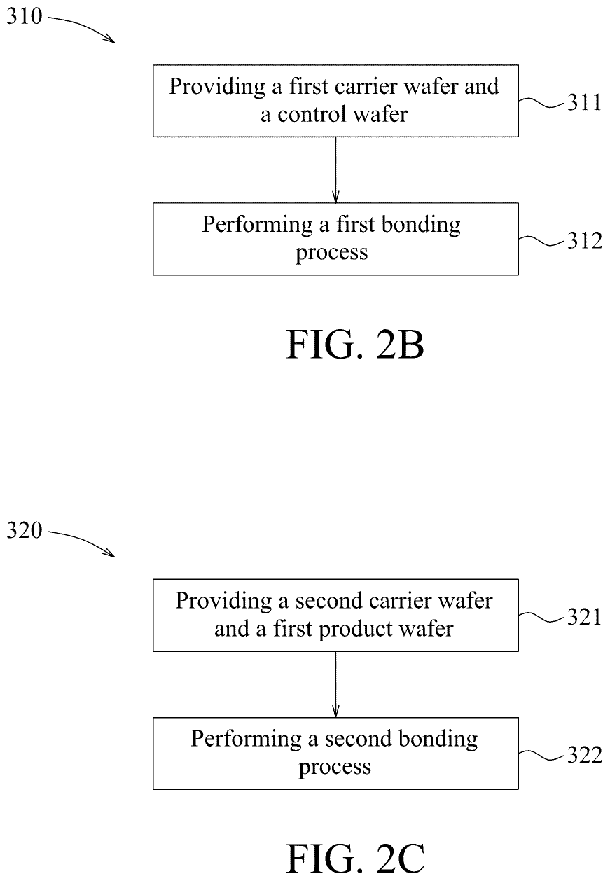

FIG. 2A is a flow diagram illustrating the method 200 for determining a parameter value to be used in the debonding tool 120 shown in FIG. 1 in accordance with some embodiments. In some embodiments, the method 200 is implemented using the system 100 shown in FIG. 1. In use, the controlling unit 160 is configured to control various components of the system 100 to perform the operation as described below. The method 200 may include steps 201, 202, 203, 204, 205, 206, 207, 208, 209, 210, 211, 212, 2031, 2051, 2091 and 2111. FIGS. 3 to 12 illustrate schematic views of intermediate stages of the method 200 in accordance with some embodiments.

Referring to FIGS. 1 and 2A, the method 200 begins at step 201, where an initial test value is assigned to a first debonding parameter to be used in the debonding tool 120. In some embodiments, based on the applicable debonding data stored in the data storage 162, the initial test value is assigned by the controlling unit 160 through the network 170. The initial test value is in a range between a first end value and a second end value which is different from the first end value. One of the first and second end values may be a maximum value for the normal operation of the debonding tool 120, and another one of the first and second end values may be a minimum value for the normal operation of the debonding tool 120.

In some embodiments, the first debonding parameter is an energy of a laser generated by the laser generator 121. In such case, the first end value is greater than the second end value. In some other embodiments, the first debonding parameter may be a depth of focus (DOF) of the laser, a location of a focal plane of the laser, a location (which may be also referred to as a chuck level) of the wafer holder 122, a spot size of the laser, a time period to be treated by the laser, or other suitable parameters. It is noted that, the term “laser” mentioned throughout this disclosure refers to laser beam(s) produced by laser device(s).

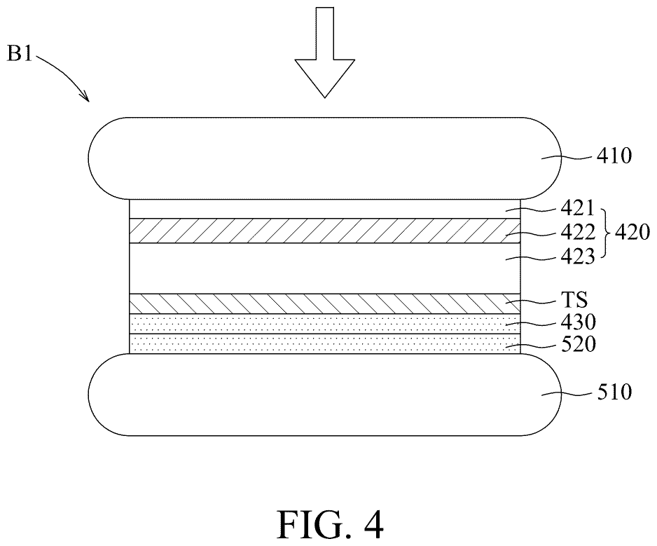

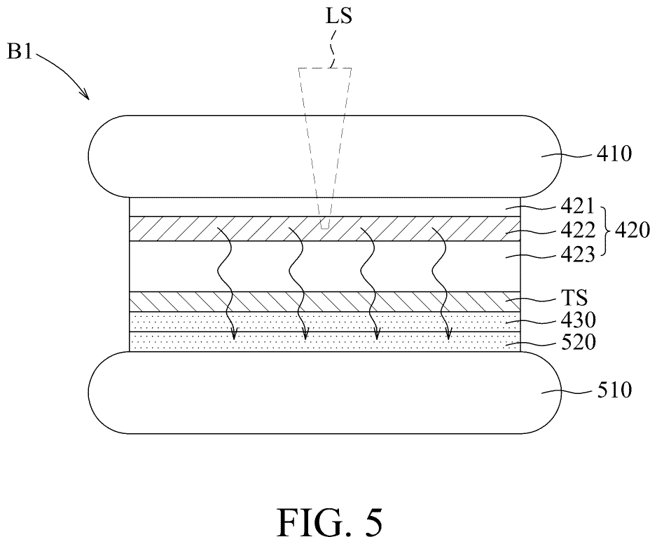

Referring to FIGS. 1 and 2A, and the examples illustrated in FIGS. 5 and 6, the method 200 proceeds to step 202, where a first debonding process is performed by the debonding tool 120 to debond a first carrier wafer 410 from a control wafer 510 using the first debonding parameter with the initial test value. In some embodiments, a laser (LS) is used in the first debonding process.

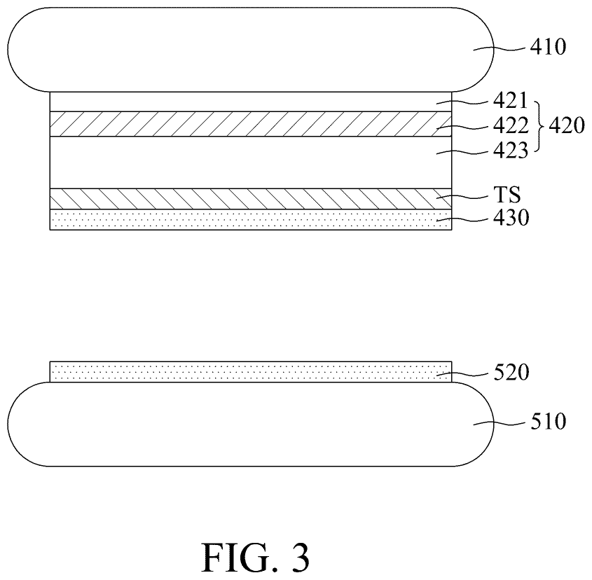

Prior to the first debonding process, the carrier wafer 410 and the control wafer 510 are bonded to each other to form a first bonded structure B1, as shown in FIG. 4. The bonded structure B1 includes the carrier wafer 410, the control wafer 510, and a temperature sensitive layer (TS) disposed between the carrier wafer 410 and the control wafer 510. The temperature sensitive layer (TS) is made of a temperature-sensitive material. That is, when the temperature sensitive layer (TS) is heated at a predetermined temperature for a period of time, the crystal phase of the temperature sensitive layer (TS) may change from a first phase (i.e., an original phase) to a second phase that is different from the first phase. In some embodiments, the temperature sensitive layer (TS) is made of titanium dioxide which includes impurities in an atomic concentration of less than about 1% and which is in an amorphous phase. In such case, the titanium dioxide layer (TS) may change from the amorphous phase to a crystalline phase (e.g., in anatase form) when the titanium dioxide layer (TS) is heated to about 280° C. or higher for a period of time greater than about 30 minutes. Therefore, the phase change of the temperature sensitive layer (TS) can be used to evaluate the degree of heating of the temperature sensitive layer (TS) in a certain state (e.g., in the first debonding process). It is noted that when a molar ratio of titanium to oxide is offset from about 1:2, or the atomic concentration of the impurities (e.g., carbon) in the temperature sensitive layer (TS) is not less than about 1%, the phase change temperature of the titanium dioxide layer (TS) may also offset from about 280° C., for example, greater than about 280° C. In some embodiments, the temperature sensitive layer (TS) may be formed by PEALD (plasma-enhanced atomic layer deposition), PECVD (plasma-enhanced chemical vapor deposition), spin-on coating, PVD (physical vapor deposition), plasma spray CVD, or other suitable deposition techniques at a temperature less than about 250° C. The density of the temperature sensitive layer (TS) may vary according to the deposition techniques used for forming the temperature sensitive layer (TS), and the phase change temperature of the temperature sensitive layer (TS) is less affected by the deposition techniques used for forming the temperature sensitive layer (TS). In some embodiments, the temperature sensitive layer (TS) may have a density ranging from about 2.1 g/cm³ to about 4.2 g/cm³. In some embodiments, the temperature sensitive layer (TS) may have a roughness less than about 100 Å. In some embodiments, the temperature sensitive layer (TS) has a thickness ranging from about 10 nm to about 100 nm. When the thickness of the temperature sensitive layer (TS) is less than about 10 nm, the crystal phase analysis of the temperature sensitive layer (TS) may become difficult. When the thickness of the temperature sensitive layer (TS) is greater than about 100 nm, the temperature sensitive layer (TS) may be partially crystalized during the deposition process thereof.

FIG. 2B is a flow diagram illustrating a method 310 for manufacturing the bonded structure B1 in accordance with some embodiments. The method 310 may include steps 311 and 312. FIGS. 3 and 4 illustrate schematic views of intermediate stages of the method 310 in accordance with some embodiments. Referring to FIG. 2B and the example illustrated in FIG. 3, the method 310 begins at step 311, where the carrier wafer 410 and the control wafer 510 are provided. The carrier wafer 410 is formed with a debonding structure 420, the temperature sensitive layer (TS) and a bonding layer 430 which are sequentially formed on the carrier wafer 410. The control wafer 510 is formed with a bonding layer 520.

In some embodiments, each of the carrier wafer 410 and the control wafer 510 includes an elemental semiconductor material (such as silicon, diamond, or germanium in crystal, polycrystalline, or an amorphous form), a compound semiconductor material (such as silicon carbide, gallium arsenide, gallium phosphide, indium arsenide, or indium phosphide), an alloy semiconductor material (such as silicon germanium, silicon germanium carbide, gallium arsenide phosphide, gallium indium phosphide, gallium indium arsenide, gallium indium arsenic phosphide, aluminum indium arsenide, or aluminum gallium arsenide), or combinations thereof. In some embodiments, each of the carrier wafer 410 and the control wafer 510 is a bulk semiconductor substrate, for example, but not limited to, a bulk substrate of silicon, germanium, silicon germanium, or other suitable semiconductor materials (such as the examples described earlier in the same paragraph). In some other embodiments not shown herein, each of the carrier wafer 410 and the control wafer 510 is configured as a semiconductor-on-insulator substrate. In some embodiments, each of the carrier wafer 410 and the control wafer 510 includes or is made of silicon. In some embodiments, each of the carrier wafer 410 and the control wafer 510 has a uniformity less than about 1%. In some embodiments, each of the carrier wafer 410 and the control wafer 510 has a roughness less than about 10 Å. Other materials and configurations suitable for each of the carrier wafer 410 and the control wafer 510 are within the contemplated scope of the present disclosure.

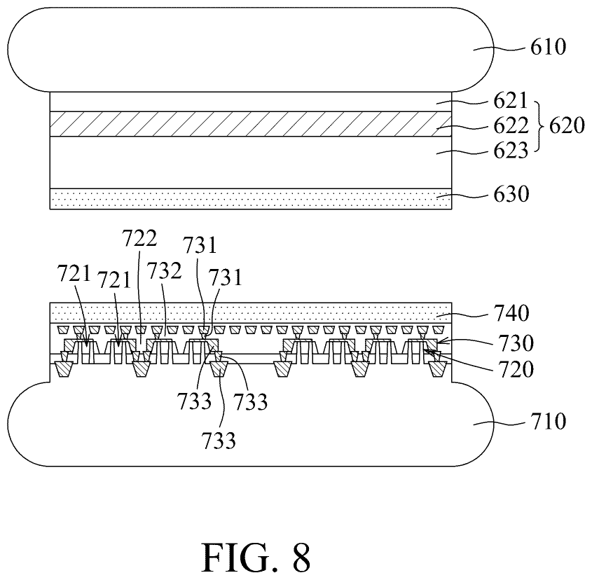

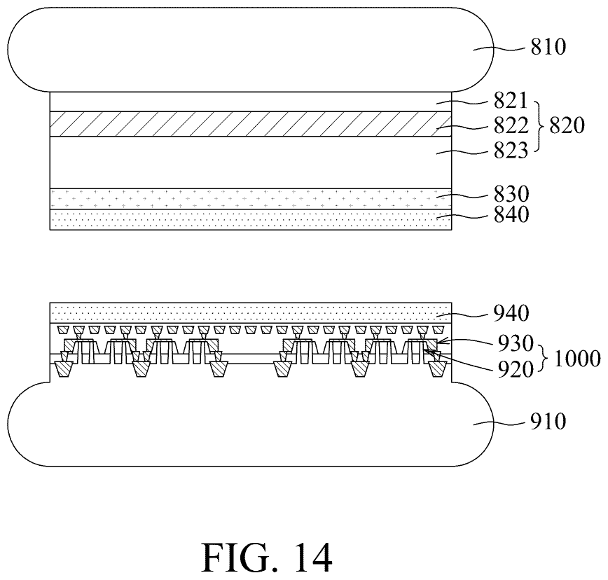

In some embodiments, the debonding structure 420 includes an adhesion layer 421, a release layer 422 and a thermal isolation layer 423 which are sequentially formed on the carrier wafer 410. The adhesion layer 421 is formed between the release layer 422 and the carrier wafer 410 so as to improve an adhesion between the release layer 422 and the carrier wafer 410. In some embodiments, the adhesion layer 421 includes or is made of silicon oxide. In some embodiments, the adhesion layer 421 includes impurities (e.g., carbon, nitrogen, etc.) in an atomic concentration of less than about 1%, so as to prevent the laser (LS) used in the first debonding process from being absorbed by the adhesion layer 421 or interfered with the adhesion layer 421. Other materials suitable for the adhesion layer 421 are also within the contemplated scope of the present disclosure. In addition, the adhesion layer 421 also functions as a heat isolation layer so as to block a heat conduction between the carrier wafer 410 and the release layer 422, thereby preventing the carrier wafer 410 from being melted. To ensure proper functions of the adhesion layer 421 without additional and unnecessary production cost, a thickness of the adhesion layer 421 is greater than about 500 Å (e.g., the thickness may range from about 550 Å to about 1000 Å, or from about 550 Å to about 700 Å). In practice, the thickness of the adhesion layer 421 may vary according to an energy of the laser (LS) used in the first debonding process. For example, when the energy of the laser (LS) is larger, the adhesion layer 421 may be thicker, so as to prevent the carrier wafer 410 from overheating and melting. The release layer 422 includes or is made of titanium nitride (e.g. TiN with columnar crystal phase), silicon oxide (e.g., SiO₂ with an amorphous phase), or other suitable materials based on a wavelength of the laser (LS), so as to permit the release layer 422 to be selectively heated by the laser (LS) used in the first debonding process. When the release layer 422 is made of titanium nitride, the release layer 422 may be formed by PVD, CVD or other suitable deposition techniques, and may have a thickness ranging from about 10 nm to about 100 nm. When the release layer 422 is made of silicon oxide, the release layer 422 may be formed by CVD, PECVD, spin-on coating, or other suitable deposition techniques, and may have a thickness ranging from about 100 nm to about 1 μm. In some embodiments, the release layer 422 may have a roughness ranging from about 0.2 nm to about 2 nm. The thermal isolation layer 423 includes a low thermal conductivity material, such as an oxide-based dielectric material, or other suitable dielectric materials. In some embodiments, the oxide-based dielectric material has a low dielectric constant (low-k) and includes a silicon oxide-based dielectric material, such as silicon oxide made from tetraethoxysilane (TEOS), silicon oxynitride, silicon oxycarbide, silicon oxycarbon nitride, or combinations thereof. To prevent the heat generated in the first debonding process (or a second debonding process described hereinafter) to be transmitted to the control wafer 510 (or a device structure 720 on a product wafer, see FIG. 9) without additional and unnecessary production cost, a thickness of the thermal isolation layer 423 is greater than about 3000 Å (e.g., the thickness may range from about 3500 Å to about 10000 Å, from about 3500 Å to about 5000 Å, or from about 3500 Å to about 5000 Å). In addition, the thickness of the thermal isolation layer 423 may be adjusted according to the wavelength of the laser (LS), the refractive index of the thermal isolation layer 423, and the extinction coefficient of the thermal isolation layer 423, so as to prevent the laser (LS) from being interfered with the thermal isolation layer 423. Furthermore, to facilitate the release layer 422 and the thermal isolation layer 423 to be separated at an interface therebetween by the first debonding process or the second debonding process, an adhesion strength between the release layer 422 and the thermal isolation layer 423 is less than an adhesion strength between the release layer 422 and the adhesion layer 421. In some embodiments, the adhesion strength between the release layer 422 and the thermal isolation layer 4233 is less than about 10 J/m² (e.g., the adhesion strength may range from about 1 J/m² to about 9 J/m², from about 3 J/m² to about 8 J/m², or from about 5 J/m² to about 8 J/m²). In some embodiments, each of the bonding layers 430, 520 includes silicon oxide, silicon oxynitride, silicon oxycarbide, silicon oxycarbon nitride, titanium oxide, aluminum oxide, nickel oxide, zinc oxide, or other suitable materials. In some embodiments, a thickness of each of the bonding layers 430, 520 ranges from about 10 nm to about 2 μm. In some embodiments, each of the bonding layers 430, 520 may have a roughness less than about 10 Å. In some embodiments, the bonding layers 430, 520 are made of the same material. Optionally, a reflective layer (e.g., element 830 shown in FIG. 14) may be provided between the bonding layer 430 and the temperature sensitive layer (TS), and the details for the reflective layer will be described hereinafter with reference to FIG. 14.

Referring to FIG. 2B and the example illustrated in FIG. 4, the method 310 proceeds to step 312, where a first bonding process is performed such that the carrier wafer 410 and the control wafer 510 are bonded to each other through the bonding layers 430, 520, thereby obtaining the bonded structure B1. FIG. 4 is a schematic sectional view similar to that shown in FIG. 3, but illustrating the structure after step 312. In some embodiments, a compressive force is applied onto the carrier wafer 410 toward the control wafer 510 retained by the wafer holder 122, such that the bonding layers 430, 520 are brought into contact with each other. Thereafter, the bonding layers 430, 520 are treated by a thermal treatment such that the bonding layers 430, 520 are bonded together through, for example, but not limited to, Si—O—Si bonds. In some embodiments, the compressive stress ranges from about 0.7 N to about 1.2 N, but other range of values are also within the contemplated scope of this disclosure. In some embodiments, the thermal treatment is performed in a manner such that the temperature sensitive layer (TS) is kept in the amorphous phase. For example, the thermal treatment is performed at a temperature ranging from about 200° C. to about 400° C. for a relatively short time period, but other range of values are also within the contemplated scope of this disclosure. In some other embodiments, the thermal treatment may be performed at a temperature ranging from about 400° C. to about 600° C. to further enhance an adhesion strength between the bonding layers 430, 520.

After the bonded structure B1 is formed, the first debonding process in step 202 may be performed. In some embodiments, the first debonding process includes sub-steps as described in the following.

First, as shown in FIGS. 1 and 4, the laser (LS) generated by the laser generator 121 passes through the carrier wafer 410 to focus on the debonding structure 420. In some embodiments, the laser (LS) may include a pulsed laser. A wavelength of the laser (LS) may be adjusted based on the material of the release layer 422. In some embodiments, when the release layer 422 is made of titanium nitride, the wavelength of the laser (LS) for selectively heating the release layer 422 ranges from about 1.7 μm to about 2.5 μm. In some embodiments, the release layer 422 may be selectively heated to a temperature ranging from about 2000° C. to about 3000° C., thereby reducing the adhesion strength between the release layer 422 and the thermal isolation layer 423 due to thermal expansion of the release layer 422. In some other embodiments, when the release layer 422 is made of silicon oxide, the wavelength of the laser (LS) for selectively heating the release layer 422 ranges from about 9 μm to 9.5 μm. In some embodiments, to ensure the proper functions of the laser (LS), an energy of the laser (LS) ranges from about 3 μJ to about 30 μJ; a depth of focus (DOF) of the laser (LS) ranges from about ±10 μm to about ±200 μm; an imprint diameter (a spot size on the focus plane) of the laser (LS) ranges from about 10 μm to about 100 μm; an energy density of the laser (LS) ranges from about 0.01 μJ/μm² to about 0.3 μJ/μm²; a distance (which may be also referred to as a line/pitch distance) between two adjacent pulsed laser spots ranges from about 10 μm to about 50 μm; the laser (LS) is applied in a dry environment, such as an environment containing air, nitrogen gas, noble gases, other suitable gases, or combinations thereof; and/or a laser pulse duration for the laser (LS) ranges from about 1 picoseconds to about 90 nanoseconds. After applying the laser (LS), as shown in FIGS. 1 and 5, a force F1, which is from the separator 124 and detected by the force detector 125, is applied to separate the carrier wafer 410 from the control wafer 510 that are respectively retained by the wafer holders 123, 122. Then, the bonded structure B1, after the first debonding process, is observed using the metrology tool 140 (e.g., GIXRD and/or TEM).

Referring to FIGS. 1 and 2A, the method 200 proceeds to step 203, where a determination as to whether the first debonding process meets a first criterion is made by the controlling unit 160 based on the data received from the debonding tool 120 and the metrology tool 140.

In some embodiments, the first criterion includes, in the first debonding process, the carrier wafer 410 is separated from the control wafer 510 via the debonding structure 420 and the force F1 is less than a first predetermined value. In addition, the first criterion further includes, in the first debonding process, the debonding structure 420 is separated into two parts which respectively remain on the carrier wafer 410 and the control wafer 510. To be specific, in some embodiments, after the first debonding process, the adhesion layer 421 and the release layer 422 of the debonding structure 420 remain on the carrier wafer 410, while the thermal isolation layer 423 of the debonding structure 420 remains on the control wafer 510. In the case that the force F1 is greater than the first predetermined value, it is indicated that the adhesion strength between the release layer 422 and the thermal isolation layer 423 after applying the laser (LS) is not reduced to a sufficiently low value. In such case, in the first debonding process, the separation may not occur at an interface between the release layer 422 and the thermal isolation layer 423. Furthermore, even if the carrier wafer 410 is separated from the control wafer 510 via the debonding structure 420, a structure (if any) between the bonding layer 520 and the control wafer 510 may be adversely affected. After the first debonding process which meets the first criterion, the temperature sensitive layer (TS) is covered by the thermal isolation layer 423.

When it is determined that the first debonding process does not meet the first criterion, the method 200 proceeds to step 2031, where a first test value, which is in a range between a current value (which, in this scenario, equals the initial test value) and the first end value, is assigned to the first debonding parameter by the controlling unit 160 through the network 170. Then, the method 200 proceeds to step 202, where the first debonding process is performed again in the debonding tool 120 but using the first debonding parameter with the first test value. To be specific, in the first debonding process, another bonded structure (similar to the bonded structure B1 shown in FIG. 4) is provided to be debonded using the first debonding parameter with the first test value. In some embodiments, when the first debonding parameter is an energy of the laser (LS), the first test value is greater than the current value and is less than the first end value.

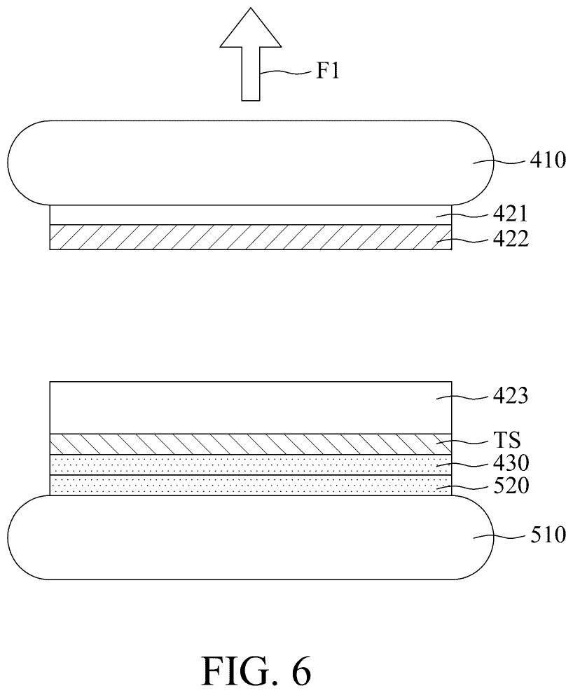

When it is determined that the first debonding process meets the first criterion, the method 200 proceeds to step 204 (referring to FIG. 1 and the example illustrated in FIG. 7), where a first treatment process is performed. The first treatment process includes a first removing step and a first analyzing step. In the first removing step, the thermal isolation layer 423 (see FIG. 6) is removed by the treating tool 130 to expose the temperature sensitive layer (TS). In the first analyzing step, the temperature sensitive layer (TS) is analyzed using the metrology tool 140 (e.g., GIXRD and/or TEM).

Referring to FIGS. 1 and 2A, the method 200 proceeds to step 205, where a determination is made as to whether the crystal phase of the temperature sensitive layer (TS) is changed. In some embodiments, the determination is made by the controlling unit 160 based on the data received from the metrology tool 140 (e.g., GIXRD and/or TEM). It is known that when a material having a crystal phase is exposed to X-rays of GIXRD or a beam of electrons of TEM, the X-rays or the beam of electrons are reflected or scattered by atoms arranged in the crystal phase, and thus a diffraction pattern can be observed. On the contrary, when a material having an amorphous phase is exposed to the X-rays or the beam of electrons, no diffraction pattern can be found. In some embodiments, an object detection process, an image recognition process or other suitable image processing procedures available on the market may be employed to detect the diffraction pattern.

In the case that the temperature sensitive layer (TS) is made of titanium dioxide which includes impurities in an atomic concentration of less than about 1% and which has an amorphous phase before the first debonding process, when the crystal phase of the temperature sensitive layer (TS) is changed from the amorphous phase to a crystalline phase after the first debonding process, it is determined that the crystal phase of the temperature sensitive layer (TS) is changed. On the contrary, when the crystal phase of the temperature sensitive layer (TS) is kept in the amorphous phase after the first debonding process, it is determined that the crystal phase of the temperature sensitive layer (TS) is not changed.

When it is determined that the crystal phase of the temperature sensitive layer (TS) is changed, the method 200 proceeds to step 2051, wherein a second test value, which is in a range between the current value and the second end value, is assigned to the first debonding parameter by the controlling unit 160. Then, the method 200 proceeds to step 202, where the first debonding process is performed again in the debonding tool 120 but using the first debonding parameter with the second test value. In some embodiments, when the first debonding parameter is an energy of the laser (LS), the second test value is less than the current value and is greater than the second end value. It is noted that each time the first debonding process is to be performed, a bonded structure similar to the bonded structure B1 shown in FIG. 4 is used, and details thereof would not be repeated hereinafter for the sake of brevity.

When it is determined that the crystal phase of the temperature sensitive layer (TS) is not changed, the method 200 proceeds to step 206, where the current value of the first debonding parameter is determined by the controlling unit 160 as a value of a second debonding parameter for a second debonding process. Then, the method 200 proceeds to step 207, where the current value of the first debonding parameter is assigned to the second debonding parameter by the controlling unit 160. After the first debonding process, the material(s) remaining on the carrier wafer 410 and the control wafer 510 may be removed so that the carrier wafer 410 and the control wafer 510 may be reused in another bonding process.

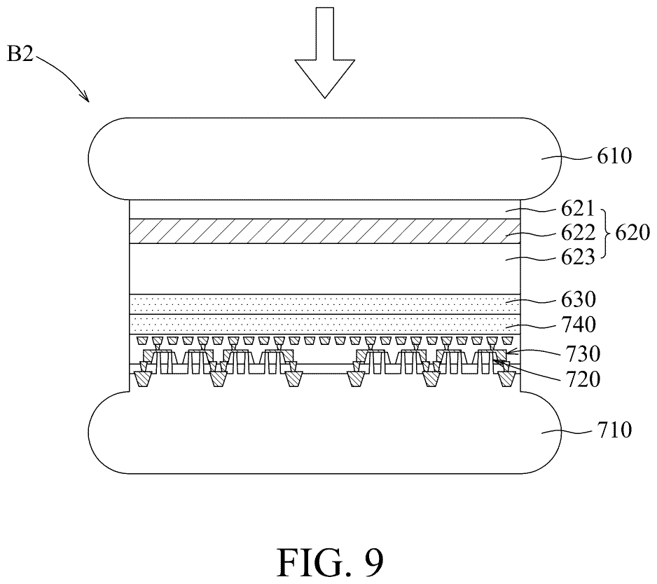

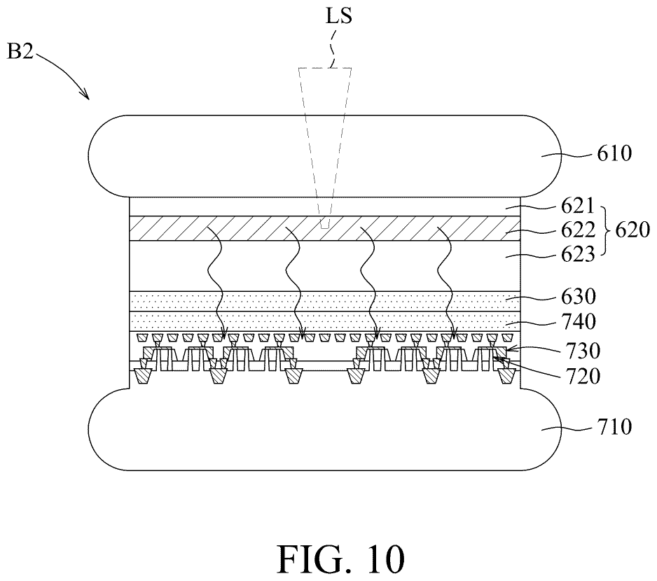

Referring to FIGS. 1 and 2A, and the examples illustrated in FIGS. 10 and 11, the method 200 proceeds to step 208, where the second debonding process is performed for debonding a second carrier wafer 610 from a first product wafer 710 using the second debonding parameter with the current value of the first debonding parameter.

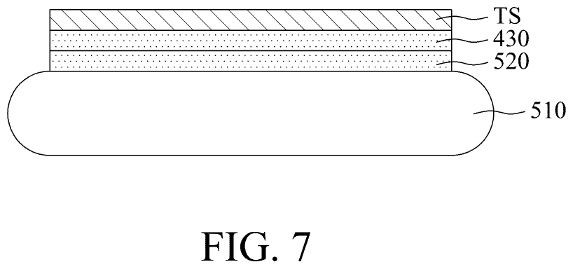

Before the second debonding process is performed, the carrier wafer 610 and the product wafer 710 are bonded to each other to form a second bonded structure B2, as shown in FIG. 9. FIG. 2C is a flow diagram illustrating a method 320 for manufacturing the bonded structure B2 in accordance with some embodiments. The method 320 may include steps 321 and 322. FIGS. 8 and 9 illustrate schematic views of intermediate stages of the method 320 in accordance with some embodiments. Referring to FIG. 2C and the example illustrated in FIG. 8, the method 320 begins at step 321, where the carrier wafer 610 and the product wafer 710 are provided. The carrier wafer 610 is formed with a bonding layer 630 and a debonding structure 620 which is disposed between the bonding layer 630 and the carrier wafer 610. The debonding structure 620 includes an adhesion layer 621, a release layer 622 and a thermal isolation layer 623 which are sequentially formed on the carrier wafer 610. Since the configuration (e.g., thickness, material, etc.) of the debonding structure 620 and the bonding layer 630 are respectively similar to the configuration of the debonding structure 420 and the bonding layer 430 shown in FIG. 3, the details thereof are omitted for the sake of brevity. The product wafer 710 is formed with a device structure 720, an interconnect structure 730 and a bonding layer 740 which are formed on the interconnect structure 730 opposite to the product wafer 710. Possible materials for the carrier wafer 610 and the product wafer 710 are similar to those for the carrier wafer 410, and thus the details thereof are omitted for the sake of brevity. In some embodiments, the product wafer 710 is a silicon substrate. In some embodiments, the device structure 720 includes semiconductor devices 721 formed in a dielectric feature 722. In some embodiments, the interconnect structure 730 includes conductive features 731 which are formed in a dielectric feature 732 and conductive features 733 which are formed in the dielectric feature 722 and extend downwardly to terminate at the product wafer 710. The conductive features 731, 733 are electrically connected to the semiconductor devices 721. The semiconductor devices 721 include planar transistors, fin-type field-effect transistors (FinFET), nanosheet semiconductor devices (e.g. gate-all-around field-effect transistors (GAAFET), forksheet field-effect transistors, complementary field-effect transistors (CFET), capacitors, resistors, decoders, amplifiers, or other suitable devices. Each of the conductive features 731, 733 may include an electrically conductive materials, such as copper, cobalt, tungsten, ruthenium, other suitable materials, or combinations thereof. Each of the dielectric features 722, 732 may include a dielectric material, such as silicon oxide, silicon oxynitride, silicon nitride, a low-k dielectric, other suitable materials, or combinations thereof. In some embodiments, possible materials suitable for the bonding layer 740 are similar to those for the bonding layers 430, 520. In some embodiments, the bonding layers 630, 740 are made of the same material. Referring to FIG. 2C and the example illustrated in FIG. 9, the method 320 proceeds to step 322, where a second bonding process is performed such that the carrier wafer 610 and the product wafer 710 are bonded to each other through the bonding layers 630, 740, thereby obtaining the bonded structure B2. FIG. 9 is a schematic sectional view similar to that shown in FIG. 8, but illustrating the structure after step 322. The second bonding process is performed in a manner similar to that of the first bonding process, and thus the details thereof are omitted for the sake of brevity.

After the bonded structure B2 is formed, the second debonding process in step 208 may be performed. In some embodiments, the second debonding process includes sub-steps as described in the following.

First, as shown in FIGS. 1 and 10, a laser (LS) generated by the laser generator 121 passes through the carrier wafer 610 to focus on the debonding structure 620. The debonding mechanism in the second debonding process is similar to that of the first debonding process, and thus the details thereof are omitted for the sake of brevity. After applying the laser (LS), as shown in FIGS. 1 and 11, a force F2, which is from the separator 124 and detected by the force detector 125, is applied to separate the carrier wafer 610 from the product wafer 710 which are respectively retained by the wafer holders 123, 122. Then, the bonded structure B2, after the second debonding process, is inspected using the defect inspection tool 150.

Referring to FIGS. 1 and 2A, the method 200 proceeds to step 209, where a determination as to whether the second debonding process meets a second criterion is made by the controlling unit 160 based on the data received from the debonding tool 120 and the defect inspection tool 150.

In some embodiments, the second criterion includes, in the second debonding process, the carrier wafer 610 is separated from the product wafer 710 via the debonding structure 620 and the force F2 is less than a second predetermined value. In addition, the second criterion further includes, in the second debonding process, the debonding structure 620 is separated into two parts which respectively remain on the carrier wafer 610 and the product wafer 710. To be specific, in some embodiments, after the second debonding process, the adhesion layer 621 and the release layer 622 of the debonding structure 620 remain on the carrier wafer 610, while the thermal isolation layer 623 of the debonding structure 620 remains on the product wafer 710. In the case that the force F2 is greater than the second predetermined value, the separation in the second debonding process may not occur at an interface between the release layer 622 and the thermal isolation layer 623. Furthermore, even if the carrier wafer 610 is separated from the product wafer 710 via the debonding structure 620, the device structure 720 and/or the interconnect structure 730 located beneath the bonding layer 740 may be adversely affected. After the second debonding process which meets the second criterion, the interconnect structure 730 is covered by the thermal isolation layer 623 and the bonding layers 630, 740.

When it is determined that the second debonding process does not meet the second criterion, the method 200 proceeds to step 2091, a third test value, which is in a range between a current value of the second debonding parameter and the first end value, is assigned to the first debonding parameter by the controlling unit 160 through the network 170. Then, the method 200 proceeds to step 202, where the first debonding process is performed again in the debonding tool 120 but using the first debonding parameter with the third test value. In some embodiments, when the first debonding parameter is an energy of the laser (LS), the third test value is greater than the current value and is less than the first end value.

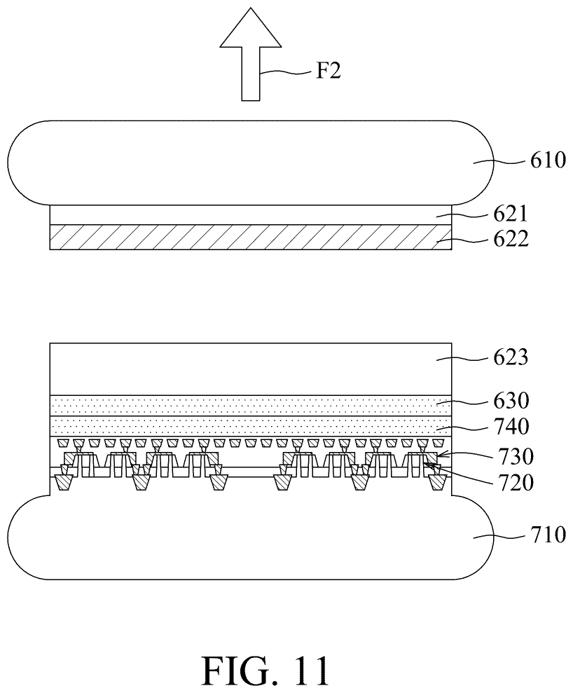

When it is determined that the second debonding process meets the second criterion, the method 200 proceeds to step 210 (referring to FIG. 1 and the example illustrated in FIG. 12), where a second treatment process is performed. The second treatment process includes a second removing step and a second analyzing step. In the first removal step, the thermal isolation layer 623 and the bonding layers 630, 740 (see FIG. 11) are removed by the treating tool 130 until the interconnect structure 730 is exposed. In the second analyzing step, the interconnect structure 730 is analyzed using the defect inspection tool 150.

Referring to FIGS. 1 and 2A, the method 200 proceeds to step 211, where a determination is made as to whether any pattern damage of the interconnect structure 730 is found. In some embodiments, the determination is made by the controlling unit 160 by comparing a first inspection data (e.g., a first image) of the interconnect structure 730 with a second inspection data (e.g., a second image) of the interconnect structure 730. The first inspection data is collected before forming the bonding layer 740, and the second inspection data is collected after the second debonding process. Both of the first and second inspection data are collected by the defect inspection tool 150 and stored in the data storage 112. In some embodiments, an image comparison process, an image similarity algorithm or other suitable image processing procedures available on the market may be employed to detect the pattern damage.

When it is determined that the pattern damage of the interconnect structure 730 is found (e.g., the second inspection data is different from the first inspection data), the method 200 proceeds to step 2111, where a fourth test value, which is in a range between the current value of the second debonding parameter and the second end value, is assigned to the first debonding parameter by the controlling unit 160. Then, the method 200 proceeds to step 202, where the first debonding process is performed again in the debonding tool 120 but using the first debonding parameter with the fourth test value. In some embodiments, when the first debonding parameter is an energy of the laser (LS), the fourth test value is less than the current value and is greater than the second end value.

When it is determined that the pattern damage of the interconnect structure 730 is not found (e.g., the second inspection data is the same with or similar to the first inspection data), the method 200 proceeds to step 212, where the current value of the second debonding parameter is determined as a value of a third debonding parameter for a third debonding process. After the second debonding process, the material(s) remaining on the carrier wafer 610 and the product wafer 710 may be removed so that the carrier wafer 610 and the product wafer 710 may be reused in another bonding process.

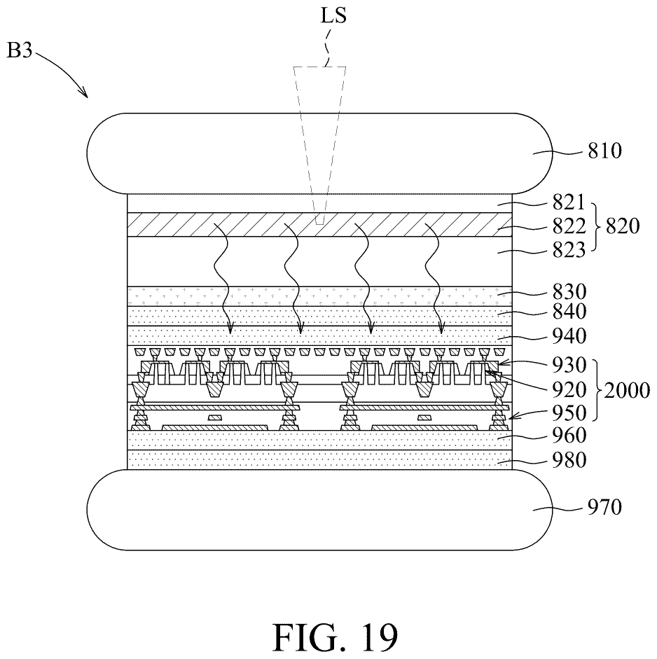

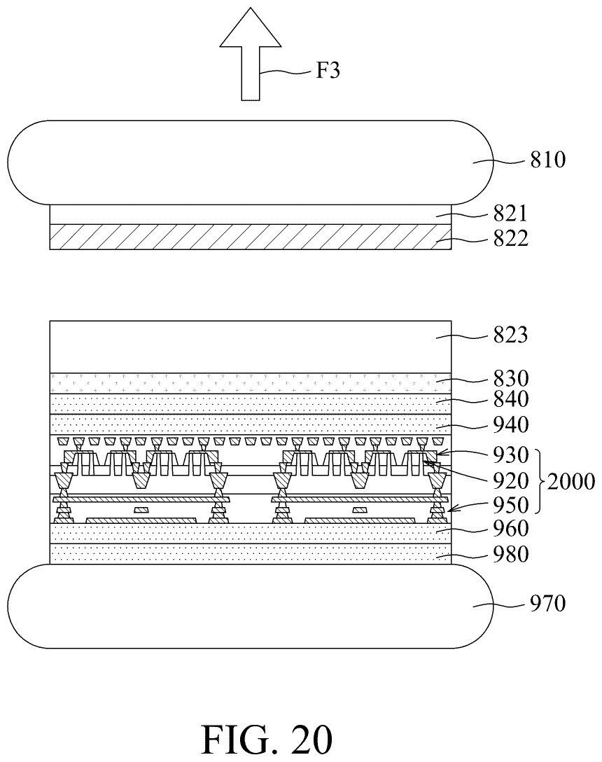

In some embodiments, the third debonding process is performed for debonding a third bonded structure B3 (see FIG. 19) using the third debonding parameter with the current value of the second debonding parameter. The bonded structure B3 includes a third carrier wafer 810, a fourth carrier wafer 970, and a semiconductor structure 2000 located between the carrier wafers 810, 970. Possible materials for the carrier wafers 810, 970 are similar to those for the carrier wafer 410, and thus the details thereof are omitted for the sake of brevity. In the third debonding process, the carrier wafer 810 is separated from the carrier wafer 970, while the semiconductor structure 2000 is left on the carrier wafer 970 (see FIG. 20). The semiconductor structure 2000 includes a device structure 920, a front interconnect structure 930, and a back interconnect structure 950. The front and back interconnect structures 930, 950 are respectively located at a front side and a backside of the device structure 920. The configuration (e.g., pattern design, layout design, etc.) of the device structure 920 and the front interconnect structure 930 are respectively similar to the configuration of the device structure 720 and the interconnect structure 730 as described above with reference to FIG. 8, and thus the details thereof are omitted for the sake of brevity. With the provision of the system 100 for implementing the method 200, the front interconnect structure 930 in the bonded structure B3 is less likely to be damaged by the laser (LS) used in the third debonding process.

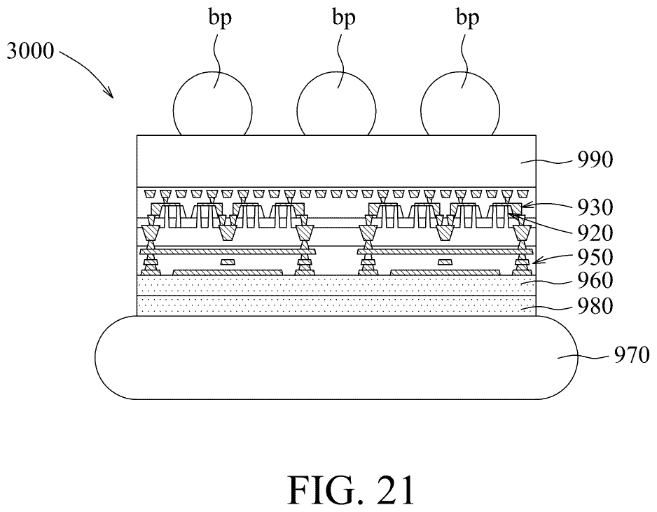

In some embodiments, the third debonding process may be performed in step 336 of a method 330 for manufacturing a semiconductor structure 3000 shown in FIG. 21. The semiconductor structure 3000 includes the device structure 920, the front interconnect structure 930 and the back interconnect structure 950.

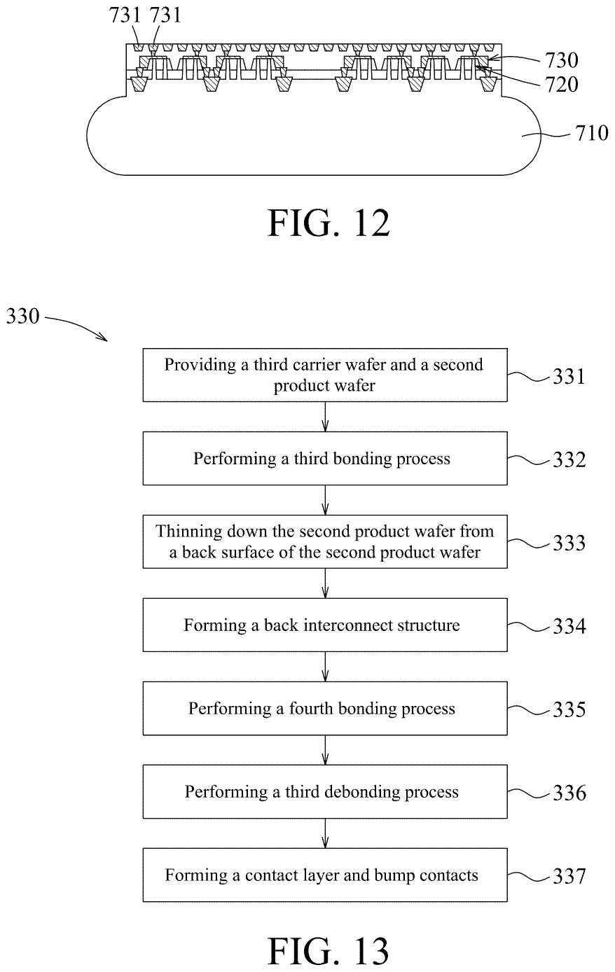

FIG. 13 is a flow diagram illustrating the method 330 in accordance with some embodiments. In some embodiments, the method 330 may include steps 331 to 337. FIGS. 14 to 21 illustrate schematic views of intermediate stages of the method 330 in accordance with some embodiments.

Referring to FIG. 13 and the example illustrated in FIG. 14, the method 330 begins at step 331, where the carrier wafer 810 and a second product wafer 910 are provided.

The carrier wafer 810 is formed with a bonding layer 840 and a debonding structure 820 which is disposed between the bonding layer 840 and the carrier wafer 810. The debonding structure 820 includes an adhesion layer 821, a release layer 822 and a thermal isolation layer 823 which are sequentially formed on the carrier wafer 810. Since the configuration (e.g., thickness, material, etc.) of the debonding structure 820 and the bonding layer 840 are respectively similar to the configuration of the debonding structure 420 and the bonding layer 430, the details thereof are omitted for the sake of brevity. In some embodiments, the carrier wafer 810 may be optionally formed with a reflective layer 830 disposed between the thermal isolation layer 823 and the bonding layer 840. The reflective layer 830 may be made of any suitable materials for reflecting the laser (LS) passing through the thermal isolation layer 823. In some embodiments, the reflective layer 830 includes or is made of a metal material (e.g., copper, ruthenium, other suitable metal materials, or combinations thereof), or a non-metal material (e.g., titanium nitride, tantalum nitride, other suitable non-metal materials, or combinations thereof. To ensure the proper functions of the reflective layer 830 without additional and unnecessary production cost, a thickness of the reflective layer 830 is greater than about 25 nm (e.g., about 25 nm to about 200 nm). In some embodiments, the reflection layer 830 has a roughness less than about 10 Å.

The product wafer 910 is formed with a semiconductor structure 1000 and a bonding layer 940 which are sequentially formed on the product wafer 910. Possible materials for the product wafer 910 are similar to those for the carrier wafer 410, and thus the details thereof are omitted for the sake of brevity. In some embodiments, the product wafer 910 is a silicon substrate. In some embodiments, the semiconductor structure 1000 includes the device structure 920 and the interconnect structure 930. In some embodiments, possible materials suitable for the bonding layer 940 are similar to those for the bonding layers 430, 520. In some embodiments, the bonding layers 840, 940 are made of the same material.

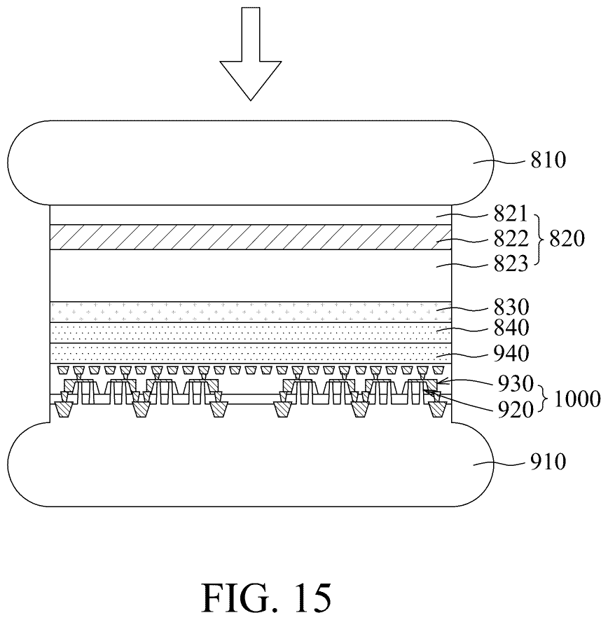

Referring to FIG. 13 and the example illustrated in FIG. 15, the method 330 proceeds to step 332, where a third bonding process is performed such that the carrier wafer 810 and the product wafer 910 are bonded to each other through the bonding layers 840, 940. FIG. 15 is a schematic sectional view similar to that shown in FIG. 14, but illustrating the structure after step 322. The third bonding process is performed in a manner similar to that of the second bonding process, and thus the details thereof are omitted for the sake of brevity.

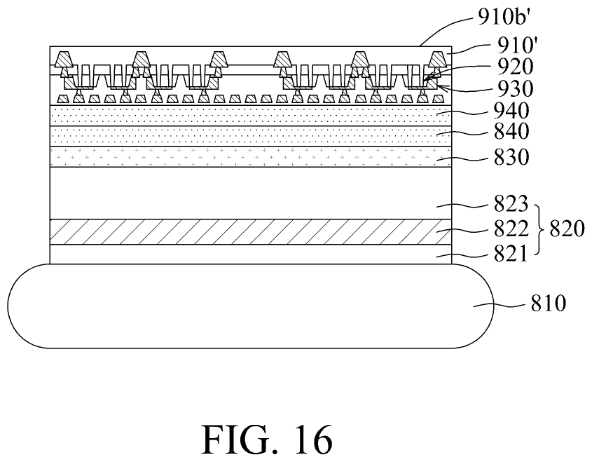

Referring to FIG. 13 and the example illustrated in FIG. 16, the method 330 proceeds to step 333, where the structure shown in FIG. 15 is flipped to place a back surface 910b of the product wafer 910 (which is opposite to the device structure 920, see FIG. 15) facing upward, and then the product wafer 910 is thinned down from the back surface 910b. FIG. 16 is a schematic sectional view similar to that shown in FIG. 15, but illustrating the structure after step 333.

In some embodiments, the product wafer 910 is thinned down by a planarization process and/or an etching process. The product wafer, after being thinned down, is denoted by the numeral 910′ and has a back surface 910b′.

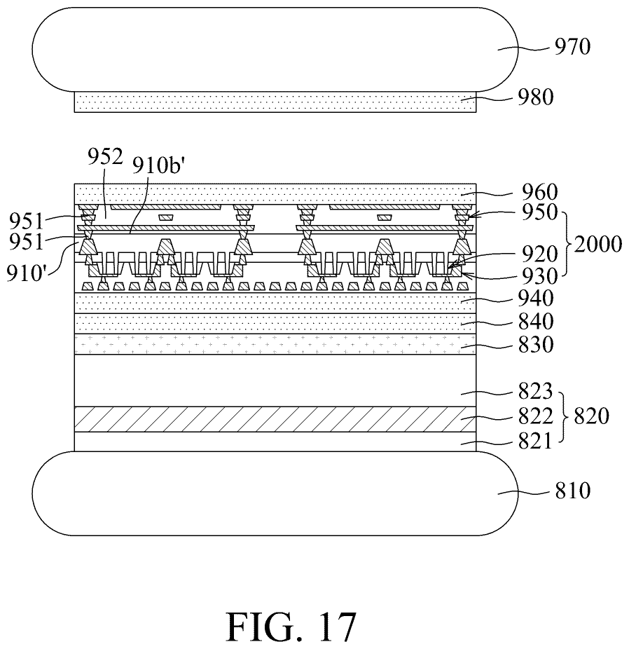

Referring to FIG. 13 and the example illustrated in FIG. 17, the method 330 proceeds to step 334, where the back interconnect structure 950 is formed on the back surface 910b′ of the product wafer 910′, thereby obtaining the semiconductor structure 2000. FIG. 17 is a schematic sectional view similar to that shown in FIG. 16, but illustrating the structure after step 334.

In some embodiments, the back interconnect structure 950 includes conductive features 951 formed in a dielectric feature 952. At least one of the conductive features 951 extends out of the dielectric feature 952 and extends in the product wafer 910′ so as to electrically connect to the front conductive features 930 or the device structure 920. Possible materials suitable for conductive features 951 and the dielectric feature 952 are respectively similar to those for the conductive features 731, 733 and the dielectric feature 732 of the interconnect structure 730, and thus the details thereof are omitted for the sake of brevity.

Before proceeding to step 335, a bonding layer 960 is formed on the back interconnect structure 950, and the carrier wafer 970 formed with a bonding layer 980 is provided. In some embodiments, possible materials suitable for the bonding layers 960, 980 are similar to those for the bonding layers 430, 520. In some embodiments, the bonding layers 960, 980 are made of the same material.

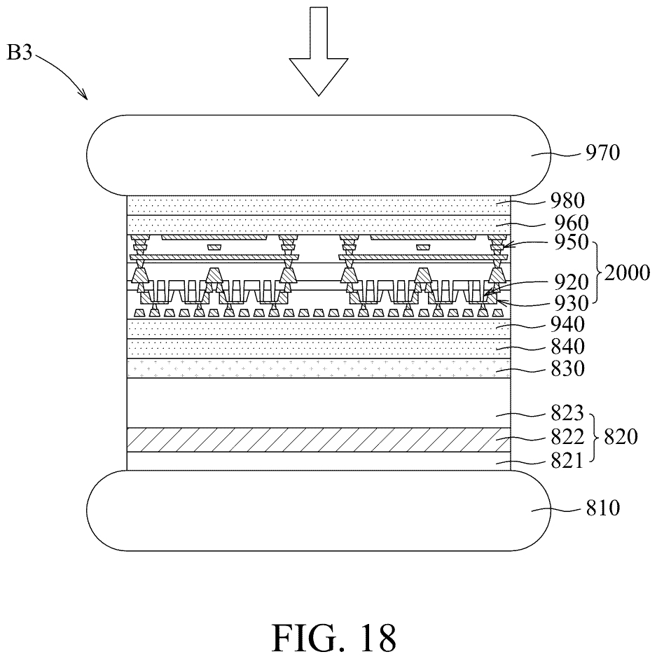

Referring to FIG. 13 and the example illustrated in FIG. 18, the method 330 proceeds to step 335, where a fourth bonding process is performed such that the semiconductor structure 2000 is bonded with the carrier wafer 970 through the bonding layers 960, 980, thereby obtaining the bonded structure B3. FIG. 18 is a schematic sectional view similar to that shown in FIG. 17, but illustrating the structure after step 335. The fourth bonding process is performed in a manner similar to that of the first bonding process, and thus the details thereof are omitted for the sake of brevity.

Referring to FIG. 13 and the examples illustrated in FIGS. 19 and 20, the method 330 proceeds to step 336, where the bonded structure B3 shown in FIG. 18 is flipped upside down so that the carrier wafer 810 is located above the carrier wafer 970, and then the third debonding process is performed for debonding the carrier wafer 810 from the carrier wafer 970 using the third debonding parameter with the value determined by the method 200 for determining a parameter value to be used in the debonding tool (which is determined in step 212 of the method 200). FIG. 20 is a schematic sectional view similar to that shown in FIG. 18, but illustrating the structure after step 336.

In some embodiments, the third debonding process includes sub-steps as described in the following.

First, as shown in FIGS. 1 and 18, a laser (LS) generated by the laser generator 121 passes through the carrier wafer 810 to focus on the debonding structure 820. The debonding mechanism in the third debonding process is similar to that of the first debonding process, and thus the details thereof are omitted for the sake of brevity. After applying the laser (LS), as shown in FIGS. 1 and 19, a force F3 is applied by the separator 124 to separate the carrier wafer 810 from the carrier wafer 970 which are respectively retained by the wafer holder 123, 122. To be specific, the carrier wafer 810 is separated from the carrier wafer 970 via the debonding structure 820. After the third debonding process, the adhesion layer 821 and the release layer 822 of the debonding structure 820 remain on the carrier wafer 810, while the thermal isolation layer 823 of the debonding structure 820 remains on the carrier wafer 970.

After the third debonding process, the material(s) remaining on the carrier wafer 810 may be removed so that the carrier wafer 810 may be reused in another bonding process.

Before proceeding to step 337, the thermal isolation layer 823, the reflective layer 830, and the bonding layers 840, 940 are removed by a planarization process, an etching process, or other suitable removal techniques, so as to expose the front interconnect structure 930.

Referring to FIG. 13 and the example illustrated in FIG. 21, the method 330 proceeds to step 337, where a contact layer 990 and bump contacts (bp) are formed, thereby obtaining the semiconductor structure 3000. FIG. 21 is a schematic sectional view similar to that shown in FIG. 20, but illustrating the structure after step 337.

The contact layer 990 is disposed on the front interconnect structure 930, and the bump contacts (bp) are disposed on the contact layer 990 opposite to the front interconnect structure 930. In some embodiments, the contact layer 990 includes a dielectric feature (not shown) and conductive features (not shown) formed in the dielectric feature. Possible materials for the dielectric feature and the conductive features in the contact layer 990 are respectively similar to the dielectric feature 732 and the conductive features 731 of the interconnect structure 730 as described above with reference to FIG. 8 and thus details thereof are omitted for the sake of brevity. The conductive features are configured to connect the front interconnect structure 930 so as to permit the devices in the device structure 920 to be electrically connected to the bump contacts (bp) through the conductive features of the front interconnect structure 930 and the conductive features of the contact layer 990.

In some embodiments, some steps in the method 200 and/or some steps in the method 330 may be modified, replaced, or eliminated without departure from the spirit and scope of the present disclosure. In some alternative embodiments, the bonded structures B1, B2, B3, and the semiconductor structure 3000 may further include additional features, and/or some features present in the bonded structures B1, B2, B3, and the semiconductor structure 3000 may be modified, replaced, or eliminated without departure from the spirit and scope of the present disclosure.

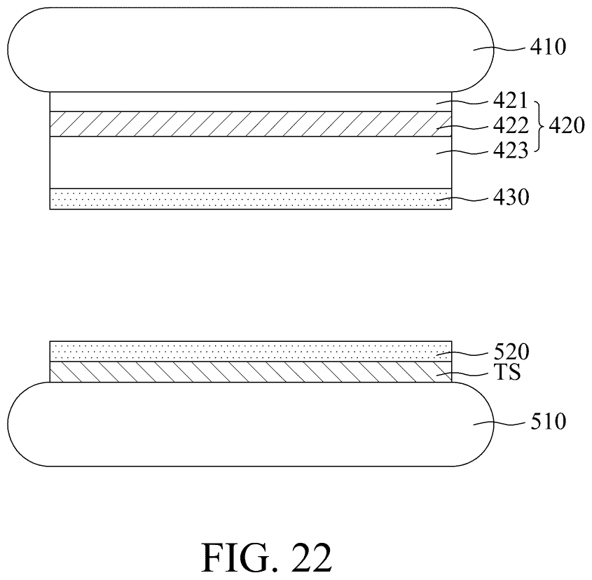

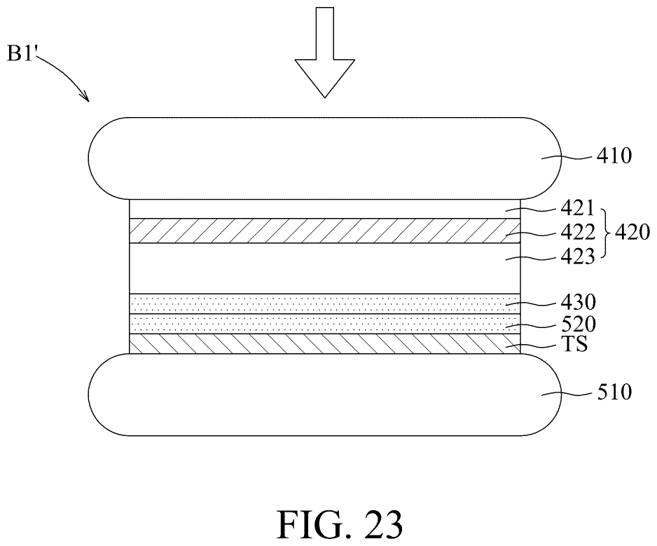

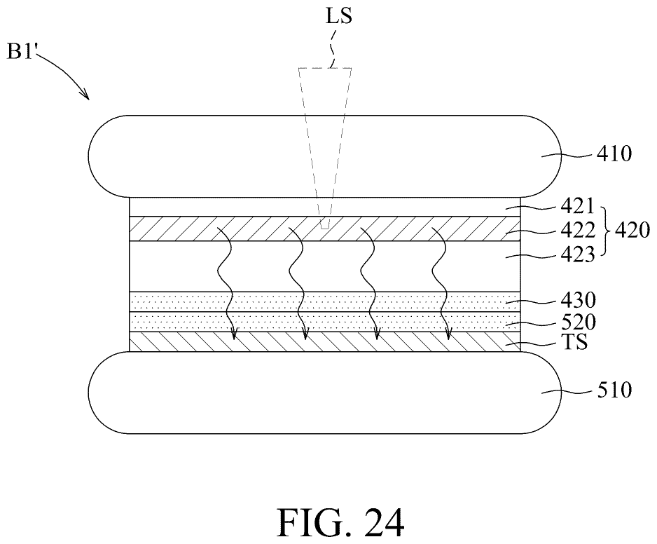

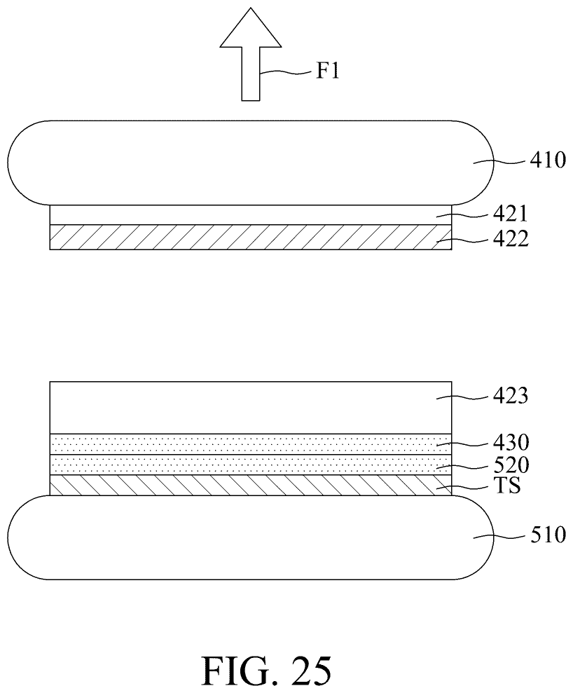

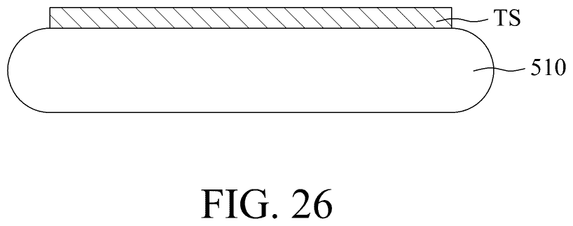

For example, in some embodiments as described above, in the bonded structure B1 (see FIG. 5) provided for the first debonding process, the temperature sensitive layer (TS) is formed between the debonding structure 420 and the bonding layer 430. FIG. 23 is a schematic sectional view illustrating a first bonded structure B1′ that has a structure similar to the structure of the bonded structure B1 shown in FIG. 4, except that the temperature sensitive layer (TS) is formed between the control wafer 510 and the bonding layer 520. The bonded structure B1′ may be formed in a manner similar to that for forming the bonded structure B1, except that, as shown in FIG. 22, in step 311, the carrier wafer 410 is formed with the debonding structure 420 and the bonding layer 430 which are sequentially formed on the carrier wafer 410, and the control wafer 510 is formed with the temperature sensitive layer (TS) and the bonding layer 520 which are sequentially formed on the control wafer 510. In the case that the bonded structure B1′ is provided for the first debonding process (see the examples illustrated in FIGS. 24 and 25 and step 202), when it is determined that the first debonding process meets the first criterion (step 203), the first removing step of the first treatment process (step 204) is performed by the treating tool 130 (see FIG. 1) to remove not only the thermal isolation layer 423 but also the bonding layers 430, 520 so as to expose the temperature sensitive layer (TS). In the first analyzing step, the temperature sensitive layer (TS, see FIG. 26) on the carrier wafer 510 is analyzed using the metrology tool 140 (e.g., GIXRD and/or TEM).

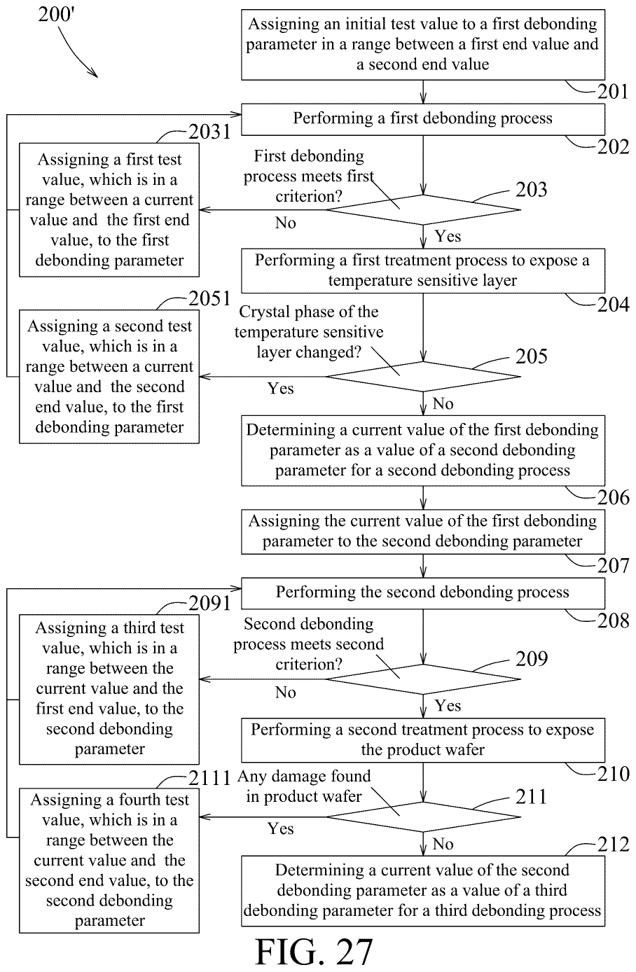

FIG. 27 is a flow diagram similar to that of FIG. 2A but illustrating a method 200′ in accordance with some other embodiments. The method 200′ is similar to the method 200 shown in FIG. 2A, but has two differences as described in the following.

In step 2091, the third test value is assigned to the second debonding parameter by the controlling unit 160 through the network 170. Then, the method 200 proceeds to step 208, where the second debonding process is performed again in the debonding tool 120 but using the second debonding parameter with the third test value. In some embodiments, when the second debonding parameter is an energy of the laser (LS), the third test value is greater than the current value and is less than the first end value.

In step 2111, the fourth test value is assigned to the second debonding parameter by the controlling unit 160 through the network 170. Then, the method 200 proceeds to step 208, where the second debonding process is performed again in the debonding tool 120 but using the second debonding parameter with the fourth test value. In some embodiments, when the second debonding parameter is an energy of the laser (LS), the fourth test value is less than the current value and is less than the first end value.

In summary, prior to the third debonding process, the third debonding parameter for the third debonding process can be determined by the method 200 using the system 100. A such, when the third debonding parameter is used in the third debonding process for separating the carrier wafer 810 from the carrier wafer 970, the semiconductor structure 2000 located between the carrier wafers 810, 970 is less likely to be damaged. Furthermore, the temperature sensitive layer (TS) included bonded structure B1, in which a blank wafer (i.e., the control wafer 510) is used for replacing the product wafer 710, is used first to screen the value of the debonding parameter (for example, but not limited to, an energy of a laser). Therefore, the manufacturing cost can be effectively reduced.

In accordance with some embodiments of the present disclosure, a method for determining a parameter value to be used in a debonding tool includes: performing a debonding process to debond a carrier wafer from a control wafer using a debonding parameter with an initial test value that is in a range between a first end value and a second end value; determining whether the debonding process meets a criterion; determining, when it is determined that the debonding process meets the criterion, whether a crystal phase of a temperature sensitive layer located between the carrier wafer and the control wafer is changed; and determining, when it is determined that the crystal phase of the temperature sensitive layer is not changed, a current value of the debonding parameter as a value of another debonding parameter for another debonding process.

In accordance with some embodiments of the present disclosure, the method further includes: when it is determined that the debonding process does not meet the criterion, assigning a first test value, which is in a range between the current value and the first end value, to the debonding parameter, and performing the debonding process using the debonding parameter with the first test value.

In accordance with some embodiments of the present disclosure, the debonding parameter is an energy of a laser, and the first test value is greater than the current value and is less than the first end value.

In accordance with some embodiments of the present disclosure, the method further includes: when it is determined that the crystal phase of the temperature sensitive layer is changed, assigning a second test value, which is in a range between the current value and the second end value, to the debonding parameter, and performing the debonding process using the debonding parameter with the second test value.

In accordance with some embodiments of the present disclosure, the debonding parameter is an energy of a laser, and the second test value is less than the current value and is greater than the second end value.

In accordance with some embodiments of the present disclosure, the method, before performing the debonding process, further includes: providing the carrier wafer and the control wafer, the carrier wafer being formed with a debonding structure, the temperature sensitive layer and a first bonding layer which are sequentially formed on the carrier wafer, the control wafer being formed with a second bonding layer; and performing a bonding process such that the carrier wafer and the control wafer are bonded to each other through the first bonding layer and the second bonding layer. The debonding process includes: applying a laser to the debonding structure; after applying the laser, applying a force to separate the carrier wafer from the control wafer; and detecting the force. The criterion for the debonding process includes, in the debonding process, the carrier wafer is separated from the control wafer via the debonding structure and the force is less than a predetermined value.

In accordance with some embodiments of the present disclosure, the criterion for the debonding process further includes, in the debonding process, the debonding structure is separated into two parts that respectively remain on the carrier wafer and the control wafer.

In accordance with some embodiments of the present disclosure, the method, before performing the debonding process, further includes: providing the carrier wafer and the control wafer, the carrier wafer being formed with a first bonding layer and a debonding structure which is disposed between the carrier wafer and the first bonding layer, the control wafer being formed with a second bonding layer and the temperature sensitive layer which is disposed between the control wafer and the second bonding layer; and performing a bonding process such that the carrier wafer and the control wafer are bonded to each other through the first bonding layer and the second bonding layer. The debonding process includes: applying a laser to the debonding structure; after applying the laser, applying a force to separate the carrier wafer from the control wafer, and detecting the force. The criterion for the debonding process includes, in the debonding process, the carrier wafer is separated from the control wafer via the debonding structure and the force is less than a predetermined value.

In accordance with some embodiments of the present disclosure, the temperature sensitive layer is made of titanium dioxide which includes impurities in an atomic concentration of less than 1%.

In accordance with some embodiments of the present disclosure, prior to the debonding process, the temperature sensitive layer has an amorphous phase. When, after the debonding process, the crystal phase of the temperature sensitive layer is changed from the amorphous phase to a crystalline phase, it is determined that the crystal phase of the temperature sensitive layer is changed.

In accordance with some embodiments of the present disclosure, a method for determining a parameter value to be used in a debonding tool includes: assigning an initial test value to a first debonding parameter, the initial test value being in a range between a first end value and a second end value; performing a first debonding process for debonding a first carrier wafer from a control wafer using the first debonding parameter with the initial test value; determining whether the first debonding process meets a first criterion; determining, when it is determined that the first debonding process meets the first criterion, whether a crystal phase of a temperature sensitive layer located between the first carrier wafer and the control wafer is changed; and determining, when it is determined that the crystal phase of the temperature sensitive layer is not changed, a current value of the first debonding parameter as a value of a second debonding parameter for a second debonding process.

In accordance with some embodiments of the present disclosure, the method further includes: assigning the current value of the first debonding parameter to the second debonding parameter; performing the second debonding process for debonding a second carrier wafer from a product wafer using the second debonding parameter; determining whether the second debonding process meets second criterion; determining, when it is determined that the second debonding process meets the second criterion, whether any pattern damage of an interconnect structure located between the second carrier wafer and the product wafer is found; and determining, when it is determined that the pattern damage of the interconnect structure is not found, a current value of the second debonding parameter as a value of a third debonding parameter for a third debonding process.

In accordance with some embodiments of the present disclosure, the method further includes: when it is determined that the second debonding process does not meet the second criterion, assigning a third test value, which is in a range between the current value and the first end value, to the first debonding parameter, and performing the first debonding process using the first debonding parameter with the third test value.

In accordance with some embodiments of the present disclosure, each of the first debonding parameter, the second debonding parameter, and the third debonding parameter is an energy of a laser, and the third test value is greater than the current value and is less than the first end value.

In accordance with some embodiments of the present disclosure, the method further includes: when it is determined that the pattern damage of the interconnect structure is found, assigning a fourth test value, which is in a range between the current value and the second end value, to the first debonding parameter, and performing the first debonding process using the first debonding parameter with the fourth test value.

In accordance with some embodiments of the present disclosure, each of the first debonding parameter, the second debonding parameter and the third debonding parameter is an energy of a laser, and the fourth test value is less than the current value and is greater than the second end value.

In accordance with some embodiments of the present disclosure, the method, before performing the second debonding process, further includes: providing the second carrier wafer and the product wafer, the second carrier wafer being formed with a first bonding layer and a debonding structure which is disposed between the first bonding layer and the second carrier wafer, the product wafer being formed with a device structure, the interconnect structure and a second bonding layer which is formed on the interconnect structure opposite to the product wafer; performing a bonding process such that the second carrier wafer and the product wafer are bonded to each other through the first bonding layer and the second bonding layer. The second debonding process includes: applying a laser to the debonding structure; after applying the laser, applying a force to separate the second carrier wafer from the product wafer; and detecting the force. The second criterion for the second debonding process includes, in the second debonding process, the second carrier wafer is separated from the product wafer via the debonding structure and the force is less than a predetermined value.

In accordance with some embodiments of the present disclosure, he temperature sensitive layer is titanium dioxide which includes impurities in an atomic concentration of less than 1%.

In accordance with some embodiments of the present disclosure, the temperature sensitive layer has a thickness ranging from 10 nm to 100 nm.

In accordance with some embodiments of the present disclosure, a method for determining a parameter value to be used in a debonding tool, includes: providing a bonded structure that includes a carrier wafer, a control wafer, a debonding structure disposed between the carrier wafer and the control wafer, a first bonding layer disposed between the debonding structure and the control wafer, a second bonding layer disposed between the first bonding layer and the control wafer, and a temperature sensitive layer disposed between the debonding structure and the first bonding layer or between the second bonding layer and the control wafer; performing a debonding process for debonding the carrier wafer from the control wafer in the bonded structure using a debonding parameter having an initial test value that is in a range between a first end value and a second end value; determining whether the debonding process meets a criterion, the criterion including the carrier wafer is separated from the control wafer via the debonding structure; determining, when it is determined that the debonding process meets the criterion, whether a crystal phase of the temperature sensitive layer is changed; and determining, when it is determined that the crystal phase of the temperature sensitive layer is not changed, a current value of the debonding parameter as a value of another debonding parameter for another debonding process.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for determining a parameter value to be used in a debonding tool, comprising:
performing a debonding process to debond a carrier wafer from a control wafer using a debonding parameter with an initial test value that is in a range between a first end value and a second end value;
determining whether the debonding process meets a criterion;
determining, when it is determined that the debonding process meets the criterion, whether a crystal phase of a temperature sensitive layer located between the carrier wafer and the control wafer is changed; and
determining, when it is determined that the crystal phase of the temperature sensitive layer is not changed, a current value of the debonding parameter as a value of another debonding parameter for another debonding process.

2. The method as claimed in claim 1, further comprising:
when it is determined that the debonding process does not meet the criterion, assigning a first test value, which is in a range between the current value and the first end value, to the debonding parameter, and performing the debonding process using the debonding parameter with the first test value.

3. The method as claimed in claim 2, wherein
the debonding parameter is an energy of a laser, and
the first test value is greater than the current value and is less than the first end value.

4. The method as claimed in claim 1, further comprising:
when it is determined that the crystal phase of the temperature sensitive layer is changed, assigning a second test value, which is in a range between the current value and the second end value, to the debonding parameter, and performing the debonding process using the debonding parameter with the second test value.

5. The method as claimed in claim 4, wherein
the debonding parameter is an energy of a laser, and
the second test value is less than the current value and is greater than the second end value.

6. The method as claimed in claim 1, before performing the debonding process, further comprising:
providing the carrier wafer and the control wafer, the carrier wafer being formed with a debonding structure, the temperature sensitive layer and a first bonding layer which are sequentially formed on the carrier wafer, the control wafer being formed with a second bonding layer; and
performing a bonding process such that the carrier wafer and the control wafer are bonded to each other through the first bonding layer and the second bonding layer,
wherein the debonding process includes
applying a laser to the debonding structure,
after applying the laser, applying a force to separate the carrier wafer from the control wafer, and
detecting the force, and
wherein the criterion for the debonding process includes, in the debonding process, the carrier wafer is separated from the control wafer via the debonding structure and the force is less than a predetermined value.

7. The method as claimed in claim 6, wherein the criterion for the debonding process further includes, in the debonding process, the debonding structure is separated into two parts that respectively remain on the carrier wafer and the control wafer.

8. The method as claimed in claim 1, before performing the debonding process, further comprising:
providing the carrier wafer and the control wafer, the carrier wafer being formed with a first bonding layer and a debonding structure which is disposed between the carrier wafer and the first bonding layer, the control wafer being formed with a second bonding layer and the temperature sensitive layer which is disposed between the control wafer and the second bonding layer; and
performing a bonding process such that the carrier wafer and the control wafer are bonded to each other through the first bonding layer and the second bonding layer,
wherein the debonding process includes
applying a laser to the debonding structure,
after applying the laser, applying a force to separate the carrier wafer from the control wafer, and
detecting the force, and
wherein the criterion for the debonding process includes, in the debonding process, the carrier wafer is separated from the control wafer via the debonding structure and the force is less than a predetermined value.

9. The method as claimed in claim 1, wherein the temperature sensitive layer is made of titanium dioxide which includes impurities in an atomic concentration of less than 1%.

10. The method as claimed in claim 9, wherein
prior to the debonding process, the temperature sensitive layer has an amorphous phase, and
when, after the debonding process, the crystal phase of the temperature sensitive layer is changed from the amorphous phase to a crystalline phase, it is determined that the crystal phase of the temperature sensitive layer is changed.

11. A method for determining a parameter value to be used in a debonding tool, comprising:
assigning an initial test value to a first debonding parameter, the initial test value being in a range between a first end value and a second end value;
performing a first debonding process for debonding a first carrier wafer from a control wafer using the first debonding parameter with the initial test value;
determining whether the first debonding process meets a first criterion;
determining, when it is determined that the first debonding process meets the first criterion, whether a crystal phase of a temperature sensitive layer located between the first carrier wafer and the control wafer is changed; and
determining, when it is determined that the crystal phase of the temperature sensitive layer is not changed, a current value of the first debonding parameter as a value of a second debonding parameter for a second debonding process.

12. The method as claimed in claim 11, further comprising:
assigning the current value of the first debonding parameter to the second debonding parameter;
performing the second debonding process for debonding a second carrier wafer from a product wafer using the second debonding parameter;
determining whether the second debonding process meets second criterion;
determining, when it is determined that the second debonding process meets the second criterion, whether any pattern damage of an interconnect structure located between the second carrier wafer and the product wafer is found; and
determining, when it is determined that the pattern damage of the interconnect structure is not found, a current value of the second debonding parameter as a value of a third debonding parameter for a third debonding process.

13. The method as claimed in claim 12, further comprising:
when it is determined that the second debonding process does not meet the second criterion, assigning a test value, which is in a range between the current value and the first end value, to the first debonding parameter, and performing the first debonding process using the first debonding parameter with the test value.

14. The method as claimed in claim 13, wherein
each of the first debonding parameter, the second debonding parameter, and the third debonding parameter is an energy of a laser, and
the test value is greater than the current value and is less than the first end value.

15. The method as claimed in claim 11, further comprising:
when it is determined that the pattern damage of the interconnect structure is found, assigning another test value, which is in a range between the current value and the second end value, to the first debonding parameter, and performing the first debonding process using the first debonding parameter with the another test value.

16. The method as claimed in claim 15, wherein
each of the first debonding parameter, the second debonding parameter and the third debonding parameter is an energy of a laser, and
the another test value is less than the current value and is greater than the second end value.

17. The method as claimed in claim 11, before performing the second debonding process, further comprising:
providing the second carrier wafer and the product wafer, the second carrier wafer being formed with a first bonding layer and a debonding structure which is disposed between the first bonding layer and the second carrier wafer, the product wafer being formed with a device structure, the interconnect structure and a second bonding layer which is formed on the interconnect structure opposite to the product wafer;
performing a bonding process such that the second carrier wafer and the product wafer are bonded to each other through the first bonding layer and the second bonding layer,
wherein the second debonding process includes
applying a laser to the debonding structure,
after applying the laser, applying a force to separate the second carrier wafer from the product wafer, and
detecting the force, and
wherein the second criterion for the second debonding process includes, in the second debonding process, the second carrier wafer is separated from the product wafer via the debonding structure and the force is less than a predetermined value.

18. The method as claimed in claim 11, wherein the temperature sensitive layer is titanium dioxide which includes impurities in an atomic concentration of less than 1%.

19. The method as claimed in claim 18, wherein the temperature sensitive layer has a thickness ranging from 10 nm to 100 nm.

20. A method for determining a parameter value to be used in a debonding tool, comprising:
providing a bonded structure that includes
a carrier wafer,
a control wafer,
a debonding structure disposed between the carrier wafer and the control wafer,
a first bonding layer disposed between the debonding structure and the control wafer,
a second bonding layer disposed between the first bonding layer and the control wafer, and
a temperature sensitive layer disposed between the debonding structure and the first bonding layer or between the second bonding layer and the control wafer;
performing a debonding process for debonding the carrier wafer from the control wafer in the bonded structure using a debonding parameter having an initial test value that is in a range between a first end value and a second end value;
determining whether the debonding process meets a criterion, the criterion including the carrier wafer is separated from the control wafer via the debonding structure;
determining, when it is determined that the debonding process meets the criterion, whether a crystal phase of the temperature sensitive layer is changed; and
determining, when it is determined that the crystal phase of the temperature sensitive layer is not changed, a current value of the debonding parameter as a value of another debonding parameter for another debonding process.
